(19) United States
(12) Patent Application Publication
(10) Pub. No.: US 2026/0024729 A1
(43) Pub. Date: Jan. 22, 2026

(54) METHOD AND APPARATUS FOR APPLYING PLASMA TO THE MID-FRAME OF AN ELECTRONIC DEVICE

(71) Applicant: Communications Test Design, Inc., West Chester, PA (US)

(72) Inventors: Stephen Tate DIJOSEPH, Downingtown, PA (US); Chris MANDEEN, West Chester, PA (US); Victor F. MAZZIO, West Chester, PA (US); Brian KENNEY, West Chester, PA (US); Christina DEBARBERIE, West Chester, PA (US)

(73) Assignee: Communications Test Design, Inc., West Chester, PA (US)

(21) Appl. No.: 19/077,393

(22) Filed: Mar. 12, 2025

Related U.S. Application Data
(60) Provisional application No. 63/673,234, filed on Jul. 19, 2024.

(51) Int. Cl. H01J 37/32

(52) U.S. Cl. CPC H01J 37/32458; H01J 2237/026; H01J 2237/24507

(57) ABSTRACT

A method and apparatus for applying plasma to the mid-frame of an electronic device is shown and described. The apparatus for applying plasma to the mid-frame of an electronic device includes a frame which creates an interior volume. The frame has a bottom portion and a top portion terminating at the top of the apparatus. A robot arm is secured to the frame. A plasma device secured to the robot arm at the end opposite the connection to the frame. A computer is operably coupled with the robot arm and the plasma device.

### CROSS REFERENCE TO RELATED APPLICATIONS

This application claims the benefit of U.S. Provisional Application No. 63/673,234 filed on Jul. 19, 2024. The above identified patent application is herein incorporated by reference in its entirety to provide continuity of disclosure.

### BACKGROUND OF THE INVENTION

Technology is always advancing and has done so at a rapid pace for the last several decades. Technology has become sophisticated, smaller, and accessible across the globe. This has led to technology becoming integral in everyday life. As with any integral element of life, the demand is high. This high demand has led to a rise in the cost of technological devices.

In addition to high demand, the simple replacement of devices can be expensive. If one merely discards older equipment or equipment with minor defects for a brand-new piece the cost can escalate quickly. If, however, technology is upgraded, or repaired this process can be much more cost effective for both the company and consumer.

Used electronic devices are often resold. However, not everyone keeps their device in a protective case. This means, normal wear and tear can cause damage to any painted surfaces of the devices. For example, mobile phones often have a metallic mid-frame which has paint or other coating placed thereon. The damage to this color can lead to a significant decrease in value. Therefore, companies which certify or refurbish phones will attempt to repaint the mid-frame of mobile devices.

Unfortunately, it is a complicated process to apply paints and coatings to metals and other materials such that they resemble the original paint, and effects, of the mobile device. Often times the paints used to create desired colors and effects do not always adhere well to the devices. This leads to chips or other blemishes quickly appearing on the refurbished device.

Other issues when applying paints or coatings to electronic devices include the application of paint to buttons and openings. In order to ensure the buttons on an electronic device continue to function as desired a coating may need to stay within a desired thickness. In one embodiment this thickness is less than 1 mm; which means this coating must be extremely durable. In addition, paint or coating substance must also stay out of or away from various openings such as charging ports or speaker openings.

Many companies have been taking advantage of the repair instead of discard philosophy. Further, many consumers are happy purchasing a lightly used and repaired device instead of a brand new one. However, these processes come with new challenges in order to remain effective. Consequently, there is always a need for an improvement in the art.

### SUMMARY OF THE INVENTION

The present invention provides a method and apparatus for painting the mid-frame of an electronic device wherein the same can be utilized creating better paint adhesion to an electronic device mid-frame when restoring the same. The apparatus for applying plasma to the mid-frame of an electronic device includes a frame which creates an interior volume. The frame has a bottom portion and a top portion terminating at the top of the apparatus. A robot arm is secured to the frame. A plasma device secured to the robot arm at the end opposite the connection to the frame. A computer is operably coupled with the robot arm and the plasma device.

Another object of the apparatus for applying plasma is to have a floor plate secured to the frame. The floor plate separates the bottom portion from the top portion.

Another object of the apparatus for applying plasma is to have a device support secured to the floor plate, within reach of the plasma device and the robot arm.

Another object of the apparatus for applying plasma is to have the robot arm secured to the top of the apparatus.

The apparatus for applying plasma of claim 1, further comprising a screen secured to the frame and operably coupled with the computer.

Another object of the apparatus for applying plasma is to have a placement apparatus secured to the robot arm.

Another object of the apparatus for applying plasma is to have a plurality of safety shields secured about the top portion.

Another object of the apparatus for applying plasma is to have the frame create four sides to the apparatus and only three sides of the top portion include the safely shield.

Another object of the apparatus for applying plasma is to have a light array bar and a corresponding part. The corresponding part is a sensor which determines when the light is disrupted.

Another object of the apparatus for applying plasma is to have the apparatus will not operate if the light from the light array bar is disrupted.

Another object of the apparatus for applying plasma is to have the computer comprised of a storage device having apparatus software stored thereon.

Another object of the apparatus for applying plasma is to have the software configured to display a graphical user interface on the screen.

Another object of the apparatus for applying plasma is to have the graphical user interface display at least one item selected from the list of items consisting of: a model selector, machine statistics, average time to complete a plasma application, live display of plasma application, the location of the plasma apparatus on an electronic device, a system checklist, an abort button, and total usage time.

Another object of the apparatus for applying plasma is to have the software configured to instruct the robot arm to move the plasma device around a particular electronic device.

Other objects, features and advantages of the present invention will become apparent from the following detailed description taken in conjunction with the accompanying drawings.

### BRIEF DESCRIPTION OF THE DRAWINGS

The accompanying drawings are incorporated in and are to be considered part of the present specification. These drawings are meant to aid the reader's understanding and comprehension of the present disclosure and are depictions of various example embodiments. The drawings are not to be considered limiting upon the disclosure. It should specifically be noted that the drawings are examples and may not necessarily be drawn to scale.

FIG. 1 shows a block diagram of a computing system.

FIG. 2A shows a front view of an example of a mobile phone device.

FIG. 2B shows a rear view of an example of a mobile phone device.

FIG. 3 shows a flow chart of one embodiment of a method for painting the mid-frame of an electronic device.

FIG. 4 shows a perspective view of one embodiment of a plasma treatment being applied to an electronic device.

FIG. 5 shows a perspective view of one embodiment of an apparatus for automatically applying plasma to the mid-frame of a mobile device.

FIG. 6 shows a zoomed view of one embodiment of the apparatus for automatically applying plasma to the mid-frame of a mobile device.

FIG. 7 shows a perspective view of one embodiment of the screen for the apparatus for automatically applying plasma to the mid-frame of a mobile device.

### DETAILED DESCRIPTION OF THE INVENTION

For the purposes of presenting a brief and clear description of the present invention, a preferred embodiment will be discussed as used for device for applying plasma to the mid-frame of an electronic device. The figures are intended for representative purposes only and should not be considered to be limiting in any respect.

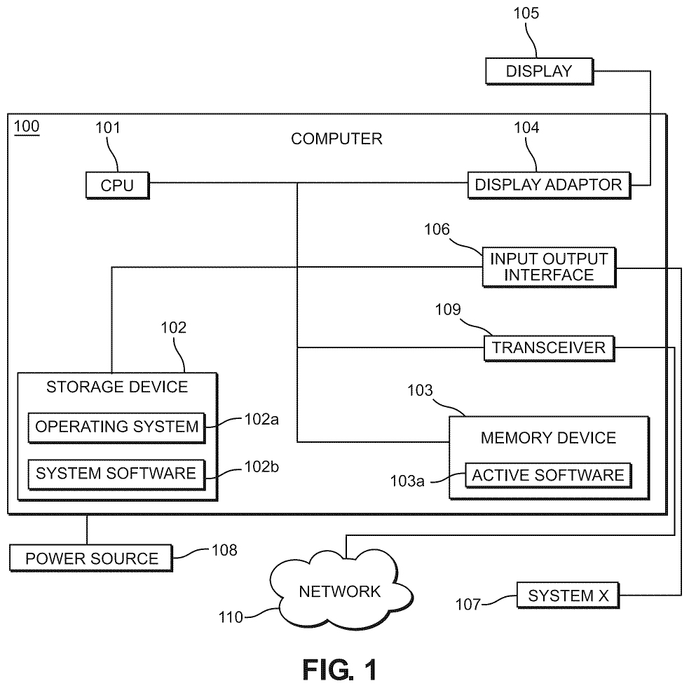

Referring now to FIG. 1, there is shown a block diagram of a computing system. Computing systems may have many interchangeable parts or multiples of some parts. One of ordinary skill in the art will understand that the shown computer 100 is a basic computing system demonstrating a minimal amount of parts to allow for the computer to function. Computer 100 is exemplary, and one of ordinary skill in the art will recognize that computer 100 may be altered as necessary to render the presently disclosed system operable or to provide a peak performance of the disclosed system.

The parts described are each operably coupled together as necessary, one of ordinary skill in the art will understand how to connect general computer components, for example by use of a mother board or other computer board. In the shown embodiment the computer 100 includes a CPU 101. In one embodiment the CPU 101 includes only one processor. In other embodiments the CPU 101 may be made up of multiple processors. Different processors will allow for different computing power and speed.

The computer 100 includes at least one storage device 102. In different embodiments the at least one storage device 102 may be a solid-state storage device, a disk storage device, or another suitable storage device. One of ordinary skill in the art will recognize that there are several types of computing storage devices each providing well-known benefits and drawbacks. The at least one storage device 102 will store at least the computer operating system 102a and system software 102b. System software 102b may include any software necessary, or optionally, used to run any system described herein.

The computer 100 will have at least one memory device 103. One of ordinary skill in the art will recognize that there are several types of computing memory devices each providing well known benefits and drawbacks. The at least one memory device 103 will store at any active software 103a. Active software 103a may include the operating system 102a or parts of the system software 102b. The at least one memory device 103 may store the entire system software 102b size and speed permitting.

The computer 100 may also include various connection ports and types. The computer 100 may have a display adaptor 104. The display adaptor 104 will allow the computer 100 to connect to at least one display 105. In other embodiments multiple displays may be connected to the display adaptor 104. Similarly, the computer 100 may include at least one input/output interface 106. The input/output interface 106 will allow the computer 100 to connect to at least one system, referred to as System X 107 in FIG. 1. The input/output interface 106 may also allow for connection to only part of System X 107 or multiple systems. The computer 100 will also be operably connected to a required power source 108.

The computer 100 may also include a transceiver 109. In one embodiment the transceiver 109 is a wired transceiver. In another embodiment the transceiver 109 is a wireless transceiver. The transceiver 109 will allow the computer 100 to connect to a network 110. The network 110 may be an internet or an intranet connection. The network 110 will allow for the computer 100 to potentially connect to multiple other computing devices. In another embodiment the network may allow for the computer 100 to connect to multiple systems. In one embodiment the computer 100 will allow for System X 107 to be connected to the network 110.

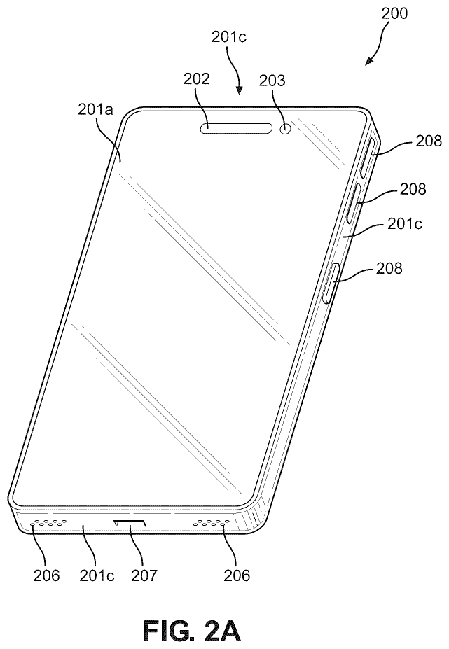

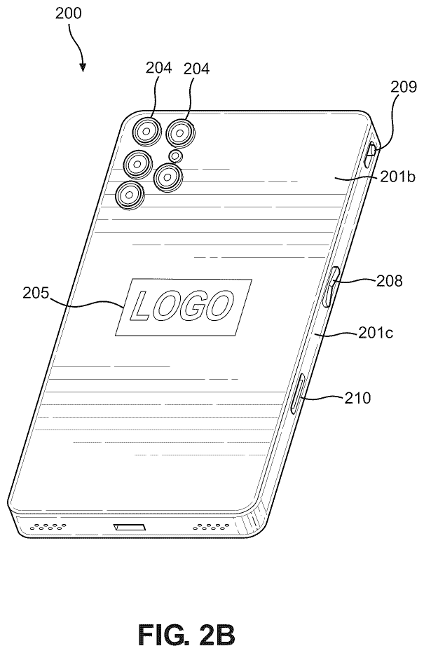

Referring now to FIG. 2A and FIG. 2B, there is shown a front view and a rear view of an example of an electronic device 200, such as a mobile phone device. Electronic devices may have many different parts and components. Even like parts or components may be in various locations or have different shapes and sizes. One of ordinary skill in the art will understand that the shown electronic device 200 is merely an example of the exterior of a device. Any specialized or specific features or requirements of devices will be detailed herein as necessary. However, one of ordinary skill in the art will understand that many electronic devices 200 have many of these described characteristics. Further, electronic devices, such as mobile phone devices, operate on a computer-based platform having many of the computer parts as described in FIG. 1. The below description seeks to detail external components and not the computer which runs the electronic device 200. The electronic device 200 can be, without limitation, a mobile phone device, or a tablet. In one embodiment other electronic devices may be used such as laptops, cable set top boxes, routers, or antennas.

The shown electronic device 200 includes a front surface 201a, a rear surface 201b, and four side surfaces 201c. The front surface 201a typically includes a screen which covers a majority of the surface. The screen is typically covered with a specialized material, currently a glass product. The front surface 201a may also include a speaker opening 202 and a camera opening 203.

The rear surface 201b of the electronic device 200 may include at least one camera lens 204. In the shown embodiment there are a plurality of camera lenses 204. In another embodiment at least one light lens is secured to the rear surface 201b. In many embodiments the rear surface 201b includes a logo 205. The logo 205 may represent the company which created the electronic device 200. The rear surface 201b may include a coating or covering to decorate or protect the rear surface. For example, a coating may be applied to the rear surface 201b to ensure a shiny surface.

The side surfaces 201c of the electronic device 200 may include any or all of the following parts. In one embodiment the electronic device 200 will have several openings for speaker output 206. The electronic device 200 will also include a charging port 207. Charging ports 207 may include a prong therein to secure to a charging cord. An electronic device 200 may include a plurality of buttons 208 along the side surfaces 201c. In different embodiments the plurality of buttons 208 may allow for volume control, locking the electronic device 200, or other desired functions. In some embodiments the electronic device 200 may include a switch 209. In yet another embodiment the electronic device 200 includes a SIM card slot or other card slot 210.

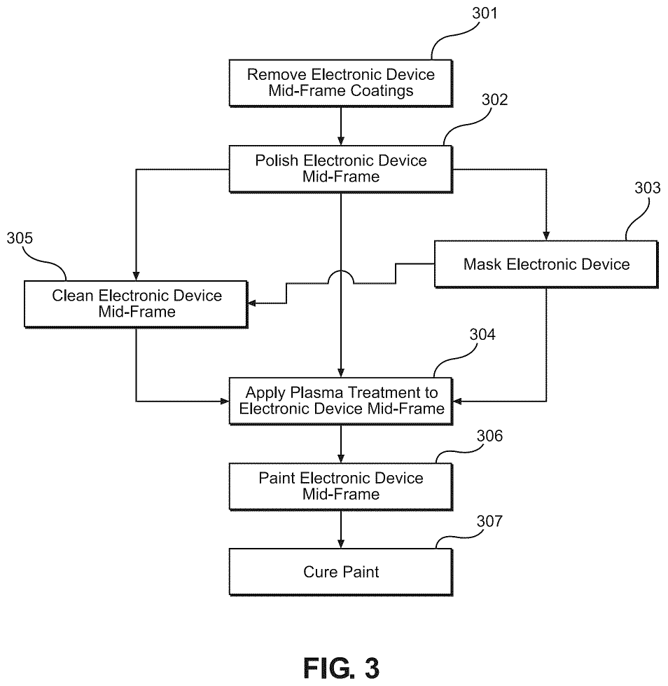

Referring now to FIG. 3, there is shown a flow chart of one embodiment of a method for painting the mid-frame of an electronic device. In order to better apply paint and coatings to mid-frames of electronic devices a cold atmospheric plasma treatment can be applied. This treatment creates a simple system which allows for paint or other coatings to adhere to the mid-frames having a superior adhesion and durability as opposed to other tested methods.

The method may begin in different places. For example, one may begin the process at the cold plasma application process. However, different steps will create different results. In one embodiment the method begins by removing factory (OEM) coatings from the mid-frame. (This process will be discussed in terms of a mid-frame, but this process can be used for any suitable surface.) In this embodiment the entire coating is removed 301. This application does not discuss the methods of removing the coatings. However, various methods can remove the coatings; different methods will produce different results. In other embodiments only a small section of the coating may be removed. This method will be discussed below.

After the coating is removed the mid-frame will need to be polished 302. This polishing process will remove burs and create a desired surface finish. In different embodiments different polishing mechanisms can be used to produce similar and desired results. After the device is polished and the desired finish has been achieved the process may progress to various steps.

In one embodiment a masking is applied to the electronic device 303.

This masking can be used to protect, for example, the screen and rear surface of an electronic device. In one embodiment the process may progress directly to the application of a cold plasma treatment 304. In another embodiment the mid-frame of the electronic device is cleaned 305. In some embodiments the device is not masked but is still cleaned.

After the desired steps are taken (masking and cleaning) the cold plasma treatment is applied to the mid-frame of the electronic device 304. In other embodiments the cold plasma treatment may be applied to other surfaces as desired. In one embodiment multiple passes are taken in an overlapping pattern. This embodiment will ensure that the plasma has adequate coverage.

After the plasma treatment has been applied 304 to the electronic device paint or other coating should be applied to the device 306. This application does not seek to describe a painting process as many different painting processes may be used to produce desired results. Further, many different paint mixtures may also be used to create desired colors and effects. One of ordinary skill in the art will be able to implement a painting method which works for them and create a paint mixture which will produce a desired color or effect without undue experimentation. After the paint is applied it should be brought to a final state in accordance with the type of paint used. In one embodiment curing may be done via an air cure 307. In another embodiment a baking curing may be required. In yet another embodiment, a vacuum curing may be required.

In the embodiment where only a small section of coating is removed. In this embodiment a process may be used to target scratches or blemished sections of an electronic device. This process also includes different processes to polish or mask the electronic device. After these steps the plasma treatment is applied to the smaller and desired area. After the treatment paint is applied only to the treated area. This modified process allows an individual to target a smaller area instead of needing to repaint an entire mid-frame.

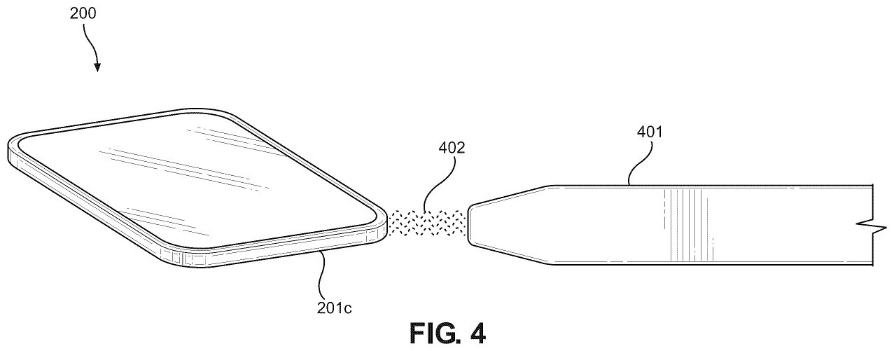

Referring now to FIG. 4, there is shown a perspective view of one embodiment of a plasma treatment being applied to an electronic device. In the present embodiment a handheld cold plasma machine 401 is used to plasma treat the edge 201c of an electronic device. In the shown embodiment the electronic device is a cellular phone. The handheld cold plasma machine 401 is used to apply the previously discussed plasma treatment to the metallic edges of the electronic device. In one embodiment a technician uses the cold plasma machine to apply the treatment. In another embodiment the entire process can be embodied in a machine process using various physical and robotic elements.

In some embodiments cold plasma machines may have different methods of creating a plasma arc 402. In some embodiments these methods may include different device heads. In one embodiment a nearfield device head is used. This embodiment will help to prevent the plasma arc 402 from damaging either the device head or the electronic device 200. In this embodiment an approximate working distance of the device head is between 0.5 mm to 2 mm. This working distance creates the best finished result. In some embodiment plasma devices will not, or cannot, generate a plasma arc unless a surface is placed within a specified proximity. In some embodiments the cold plasma machine will have an automatic shut off if no arch is created within a specified time.

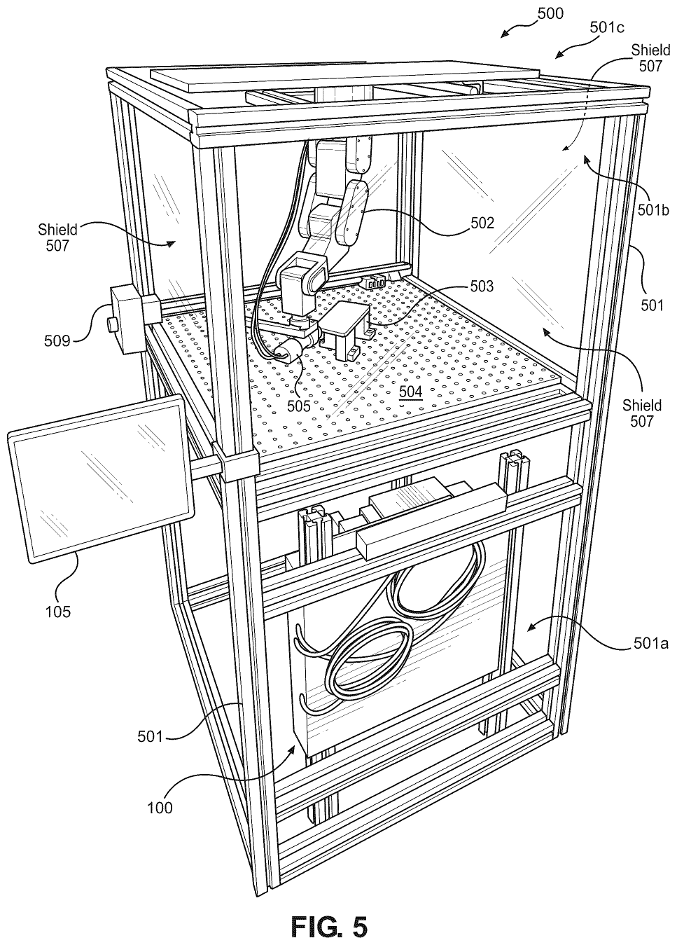

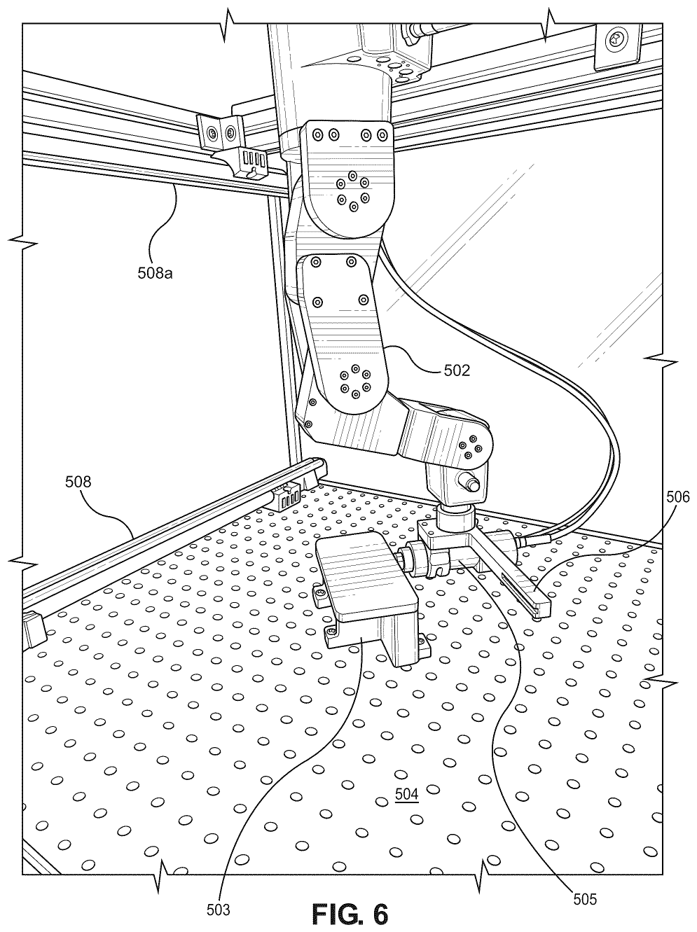

In FIG. 5-FIG. 7 there is shown an apparatus for automatically applying the plasma treatment described herein to the mid-frame of a mobile device. Referring now to FIG. 5 and FIG. 6, there is shown a perspective view and a zoomed view, respectively, of one embodiment of an apparatus for automatically applying plasma to the mid-frame of a mobile device. The apparatus for automatically applying plasma 500 includes a frame 501. The frame 501 has a bottom portion 501a and a top portion 501b. In the shown embodiment the bottom portion 501a is configured to secure the computer 100 components required by the system. The screen 105 can be secured along the frame 501.

In the shown embodiment the top portion 501b is configured to secure other system components. A robot arm 502 is secured to the frame 501. In the shown embodiment the robot arm 502 is hanging down from the top of the frame 501c. This allows the robot arm to move around a mobile device support 503. The mobile device support 503 is secured to a floor plate 504. The mobile device support 503 is configured to hold a device thereon. In one embodiment the edges of the a mobile device placed on the mobile device support 503 will hang over the edges of the mobile device support 503. This will help when plasma is applied to the mid-frame of the mobile device.

The end of the robot arm 502 not attached to the frame may have a plurality of components secured thereto. In one embodiment the robot arm 502 has a plasma device 505 secured thereto. This will allow for the robot arm 502 to move the plasma device 505 around a mobile device in a precise manner.

In one embodiment the robot arm 502 has a placement apparatus 506 attached. The placement apparatus is configured to move a mobile device once it has been placed on the mobile device support 503. In one embodiment the placement apparatus 506 is L shaped. This will enable a mobile device to have at least two sides pressed against in order to properly position the mobile device.

In some embodiments a safety shield 507 can be secured to the frame 501. In the shown embodiment the safety shield 507 is secured to three sides of the frame about the top section 501b. A fourth side is left open to enable access to the interior of the top section 501b. In one embodiment a light array bar (What is it actually called) 508 is placed along the base of the fourth side. The light array bar 508 has a corresponding part 508a along the top of the fourth side. In one embodiment the corresponding part 508a is a light sensor. The light array bar 508 will send a light beam to the corresponding part 508a. If a break in the light is detected the system will not activate. In one embodiment in order to enhance the safety of the device an emergency shutoff button 509 is secured to the frame. If the emergency shutoff button is pressed the system will immediately shut down.

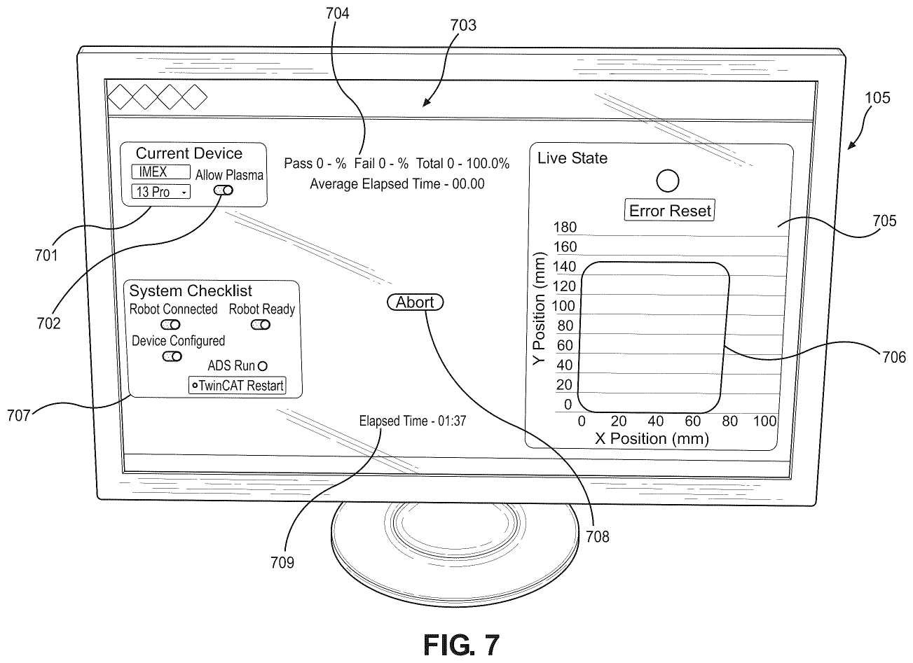

Referring now to FIG. 7, there is shown a perspective view of one embodiment of the screen for the apparatus for automatically applying plasma to the mid-frame of a mobile device. The screen 105 is configured to display a graphical user interface (GUI) which will have several buttons for system control as well as system statistics. The specific locations of the various components may be changed to fit a user's need.

In the shown embodiment the top left corner displays a model selection 701 drop down menu. This will allow the user to select the type of electronic device to have plasma applied. In some embodiments there is a selector 702 to enable the plasma device. In the upper middle of the screen 105 there is a plurality of machine statistics 703. For example, the pass and fail results of the electronic devices which have had plasma applied. In some embodiments there is shown the average time it take to apply the plasma treatment to an electronic device 704.

On the right of the screen 105 there is a live display of the plasma application 705. In one embodiment the exact path of the plasma around an electronic device 706 is shown. This allows a user to determine if a section was missed. In the lower left of the screen 105 a system check list 707 is displayed. The system check list 707 is used to determine if the system is ready for use. In the shown embodiment, the system check list 707 shows toggles to display if the robot arm is connection, if the robot arm is responsive, and if the system is configured for the chosen device.

In one embodiment, an abort button 708 is located in the center of the screen 105. This is just one more safety feature for the system which allows a user to shut down the system if needed. Lastly, the total usage time 709 is displayed in the lower middle of the screen 105. The total usage time 709 shows the total run time of the system over its lifetime.

It is therefore submitted that the methods, systems, and devices have been shown and described in what is considered the most practical and preferred embodiments along with specific examples. It is recognized, however, that departures may be made within the scope and these present examples are not intended to be limiting. One of ordinary skill the art will be able to discern that obvious modifications can be made without departing from the scope or spirit.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention. Similarly, it is to be realized that, it is not intended for any method set forth herein to be construed as requiring that its steps be performed in a specific order, unless otherwise set forth in the claims.

Therefore, the foregoing is considered as illustrative only of the principles of the disclosure. Further, since numerous modifications and changes will readily occur to those skilled in the art, it is not desired to limit the invention to the exact construction and operation shown and described, and accordingly, all suitable modifications and equivalents may be resorted to, are deemed to fall within.

What is claimed:

1. An apparatus for applying plasma to the mid-frame of an electronic device, the apparatus comprising:
a frame creating and interior volume, wherein the frame has a bottom portion and a top portion terminating at the top of the apparatus;
a robot arm is secured to the frame;
a plasma device secured to the robot arm at the end opposite the connection to the frame;
a computer operably coupled with the robot arm and the plasma device.

2. The apparatus for applying plasma of claim 1, further comprising a floor plate secured to the frame, wherein the floor plate separates the bottom portion from the top portion.

3. The apparatus for applying plasma of claim 1, further comprising a device support secured to the floor plate, within reach of the plasma device and the robot arm.

4. The apparatus for applying plasma of claim 1, wherein the robot arm is secured to the top of the apparatus.

5. The apparatus for applying plasma of claim 1, further comprising a screen secured to the frame and operably coupled with the computer.

6. The apparatus for applying plasma of claim 1, further comprising a placement apparatus secured to the robot arm.

7. The apparatus for applying plasma of claim 1, comprising a plurality of safety shields secured about the top portion.

8. The apparatus for applying plasma of claim 7, wherein the frame creates four sides to the apparatus and only three sides of the top portion include the safely shield.

9. The apparatus for applying plasma of claim 8, further comprising a light array bar and a corresponding part, wherein the corresponding part is a sensor which determines when the light is disrupted.

10. The apparatus for applying plasma of claim 9, wherein the apparatus will not operate if the light from the light array bar is disrupted.

11. The apparatus for applying plasma of claim 1, wherein the computer is comprised of a storage device having apparatus software stored thereon.

12. The apparatus for applying plasma of claim 11, wherein the software is configured to display a graphical user interface on the screen.

13. The apparatus for applying plasma of claim 11, wherein the graphical user interface displays at least one item selected from the list of items consisting of: a model selector, machine statistics, average time to complete a plasma application, live display of plasma application, the location of the plasma apparatus on an electronic device, a system checklist, an abort button, and total usage time.

14. The apparatus for applying plasma of claim 11, wherein the software is configured to instruct the robot arm to move the plasma device around a particular electronic device.
